(19) United States
(12) Patent Application Publication
(10) Pub. No.: US 2013/0208413 A1
(43) Pub. Date: Aug. 15, 2013

(54) NETWORK ATTACHED STORAGE DEVICE AND ASSEMBLING METHOD THEREOF

(71) Applicant: Yi-Kuei Huang, New Taipei City (TW)

(72) Inventor: Yi-Kuei Huang, New Taipei City (TW)

(21) Appl. No.: 13/720,935

(22) Filed: Dec. 19, 2012

(30) Foreign Application Priority Data
Feb. 10, 2012 (TW) 101202496

(51) Int. Cl. G06F 1/18; H05K 13/00

(52) U.S. Cl. CPC G06F 1/183; H05K 13/00
USPC 361/679.31; 29/825

(57) ABSTRACT

A network attached storage device (NAS) includes a chassis, a circuit board module and at least one storage unit. The chassis has a first opening, at least one second opening and at least one first positioning assembly, in which the first positioning assembly is located beside the second opening. The circuit board module is placed into the chassis via the second opening. The circuit board module has at least one bracket and the bracket is located at the second opening and interferes with the first positioning assembly along a locking direction. The storage unit is placed into the chassis via the first opening so as to be assembled and electrically connected to the circuit board module. In addition, a method of assembling an NAS is also disclosed.

### CROSS-REFERENCE TO RELATED APPLICATION

This application claims the priority benefit of Taiwan application serial no. 101202496, filed on Feb. 10, 2012. The entirety of the above-mentioned patent application is hereby incorporated by reference herein and made a part of this specification.

### BACKGROUND OF THE INVENTION

1. Field of the Invention

The invention generally relates to a network device, and more particularly, to a network attached storage device (NAS) and an assembling method thereof.

2. Description of Related Art

In the modern era of LAN (local area network) with high wide-spreading rate, within an enterprise the LAN is widely used to access the internal data. A study has revealed that in small and medium enterprises (SMEs), some files or data operated by the internal computers thereof are repeatedly used. Hence, it should be reduced to transmit the repeatedly used files or data between computers so as to release the burdens of the computer host systems.

In this regard, the relevant manufactures have provided an NAS for interconnecting the internal computers based on an LAN framework through utilizing the convenience thereof. In this way, all the computers in an enterprise are able to capture the files or data stored in the NAS through the LAN connections between the computers. Moreover, the NAS can provide the clients and the server-sides of various platforms or systems (including Unix, Windows, Linux, Netware, etc.) with storage units for sharing files.

The NAS is an IP protocol-based device and used on an Ethernet network to manage the information flow on the LAN through a dedicated file server and provide various different servers and workstations with a common data storage protocol therebetween. Since the file server of the NAS is dedicated to data access operations, so that there is no need to assign additional spaces to the rest servers and these servers have more spaces to handle other instructions. It can be seen that the most important feature of the NAS rests in assigning the storage spaces to different servers or workstations to make the data files shared on the network. Accordingly, in an NAS, at least one hard drive is normally employed and an operation system (OS) is installed at a dedicated file server of the hard drive for the NAS.

### SUMMARY OF THE INVENTION

Accordingly, the invention is directed to an NAS with a better structure design for facilitating assembling.

The invention provides an NAS, which includes a chassis, a circuit board module and at least one storage unit. The chassis has a first opening, at least one second opening and at least one first positioning assembly, in which the first positioning assembly is located beside the second opening. The circuit board module is placed into the chassis via the second opening, in which the circuit board module has at least one bracket and the bracket is located at the second opening and interferes with the first positioning assembly along a locking direction. The storage unit is placed into the chassis via the first opening so as to be assembled and electrically connected to the circuit board module.

In an embodiment of the present invention, the above-mentioned first opening is located on a first plane, both the second opening and the first positioning assembly are located on a second plane, and the first plane is perpendicular to the second plane.

The invention provides a method of assembling an NAS for assembling the above-mentioned NAS. The method of assembling an NAS includes: placing the circuit board module into the chassis along an axis via one of the second openings; rotating the circuit board module along a locking direction to make at least one bracket of the circuit board module interfere with the first positioning assembly; fixing the bracket to the chassis; placing the storage unit into the chassis via the first opening; and assembling and electrically connecting the storage unit to the circuit board module.

In an embodiment of the present invention, the above-mentioned second plane is formed by a first axis and a second axis orthogonal to each other and the first axis is perpendicular to the first plane.

In an embodiment of the present invention, the above-mentioned circuit board module includes a carry frame and a circuit board. The bracket extends towards the second opening from the carry frame to be assembled to the chassis. The circuit board is assembled on the carry frame and together with the carry frame parallel to the second axis, in which the storage unit is inserted to the circuit board along the first axis.

In an embodiment of the present invention, the above-mentioned chassis has two second openings respectively located on two second planes parallel to each other, the first plane is perpendicular to the two second planes and the orthogonal projections of the two second openings on the first plane are respectively located at both opposite sides of the first opening.

In an embodiment of the present invention, the above-mentioned circuit board module includes two brackets respectively extending to the two second openings from the carry frame, in which the orthogonal projections of the two brackets and the circuit board on a third plane taking the second axis as the normal thereof are in a H-shape.

In an embodiment of the present invention, the above-mentioned first positioning assembly includes a first element and a second element respectively leaning against both opposite sides of the bracket, and the first element and the second element on the second plane are located on different lines parallel to the second axis.

In an embodiment of the present invention, the above-mentioned first element and second element on the second plane are disposed at upper-left and lower-right positions or lower-left and upper-right positions relatively to the bracket.

In an embodiment of the present invention, the above-mentioned first element and second element respectively have a first retaining portion, the bracket gets interference between the two first retaining portions, and each of the first retaining portions on the second plane is a line segment parallel to the second axis.

In an embodiment of the present invention, the above-mentioned chassis has a pair of side-edges opposite to each other beside the second opening, the bracket further has a second positioning assembly, and the second positioning assembly leans against the pair of side-edges along the second axis.

In an embodiment of the present invention, the above-mentioned second positioning assembly includes a third element and a fourth element arranged along the second axis, the third element and the fourth element respectively have a second retaining portion leaning against the pair of side-edges, and each of the second retaining portions projected on the second plane is a line segment parallel to the first axis.

In an embodiment of the present invention, a length of the above-mentioned second opening along the first axis is greater than a length of the bracket along the first axis, and a length of the second opening along the second axis is less than a length of the bracket along the second axis.

In an embodiment of the present invention, the above-mentioned first plane is formed by a third axis and a fourth axis orthogonal to each other, in which the third axis is perpendicular to the second plane, a length of the first opening along the third axis is less than a length of the bracket along the third axis, and a length of the first opening along the fourth axis is less than a length of the bracket along the fourth axis.

In an embodiment of the present invention, a projection of the above-mentioned locking direction on the second plane is in a clockwise direction or a counter-clockwise direction.

In an embodiment of the present invention, the above-mentioned NAS further includes at least one screw, in which the bracket has at least one first fastening hole, the chassis has at least one second fastening hole, when the bracket interferes with the first positioning assembly along the locking direction, the first fastening hole is aligned with the second fastening hole, and the screw is fastened at the first fastening hole and the second fastening hole to fix the bracket on the chassis.

Based on the description above, in the above-mentioned embodiments of the invention, the circuit board module of the NAS can rotate in a specific direction through the bracket thereof and be locked at the chassis, further the circuit board module can be assembled to the chassis in locking way or fastening way. By using the above-mentioned appropriate structure design, the NAS of the invention is convenient for a user to assemble the circuit board module into the chassis and the effect of assembling the NAS is advanced.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIGS. 1 and 2 are schematic diagrams of an NAS in different angles-of-view according to an embodiment of the invention.

FIG. 3 is a schematic diagram of the circuit board module in the NAS of FIG. 1.

FIG. 4 is a side-view of the NAS of FIG. 1.

FIG. 5 is a diagram of the NAS of FIG. 1 in another angles-of-view.

FIG. 6 is a flowchart of assembling an NAS according to an embodiment of the invention.

FIGS. 7 and 8 are schematic diagrams corresponding to partial flowcharts of FIG. 6.

### DESCRIPTION OF THE EMBODIMENTS

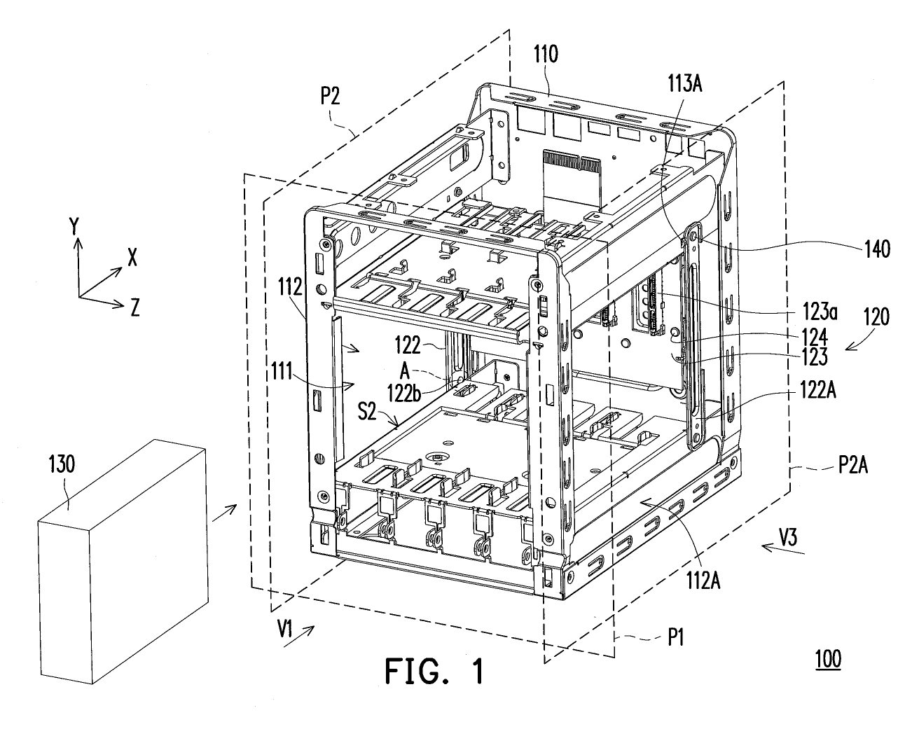

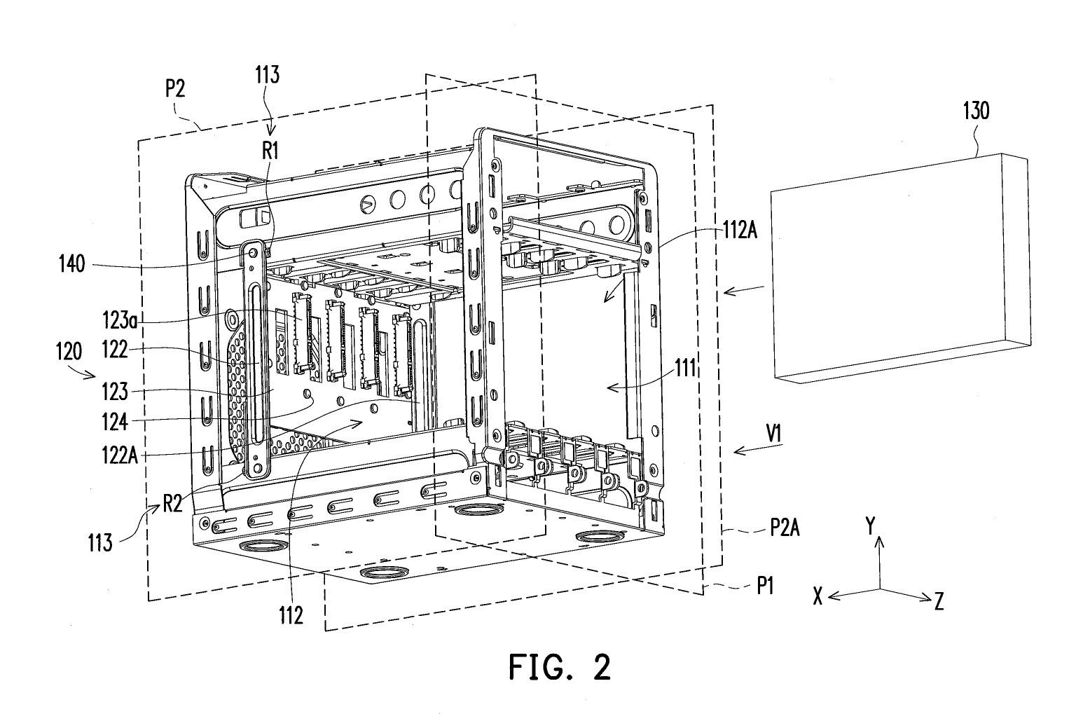

FIGS. 1 and 2 are schematic diagrams of an NAS in different angles-of-view according to an embodiment of the invention. For better distinguishing the relationships between related sub-assemblies, an NAS 100 of the embodiment is illustrated without the outer parts, and meanwhile a Cartesian coordinates system is defined to facilitate the following description and understanding. Referring to FIG. 1, in the embodiment, the NAS 100 includes a chassis 110, a circuit board module 120 and a storage unit 130, in which only one storage unit 130 is shown in the embodiment but not limited to. The chassis 110 has a first opening 111, two second openings 112 and 112A and two first positioning assemblies 113 and 113A, and the first positioning assemblies 113 and 113A are respectively located beside the second openings 112 and 112A. The first opening 111 is located on a first plane P1, the second openings 112 and 112A are respectively located on two second planes P2 and P2A parallel to each other, and the first plane P1 is perpendicular to the two second planes P2 and P2A. The orthogonal projections of the two second openings 112 and 112A herein on the first plane P1 are respectively located at both opposite sides of the first opening 111.

The circuit board module 120 is suitable to be placed into the chassis 110 via the second opening 112 or 112A. The circuit board module 120 has two brackets 122 and 122A. When the circuit board module 120 is located in the chassis 110, the two brackets 122 and 122A are located at the second openings 112 and 112A, which means at the time, the bracket 122, the second opening 112 and the first positioning assembly 113 are respectively located on the same second plane P2, while the bracket 122A, the second opening 112A and the first positioning assembly 113A are respectively located on the same second plane P2A.

Since the NAS 100 is a left-right symmetry structure in angle-of-view V1, only one side thereof (at the second opening 112) is described in details in the embodiment, while the other side (at the second opening 112A) is omitted to describe and understood from the situation at the second opening 112.

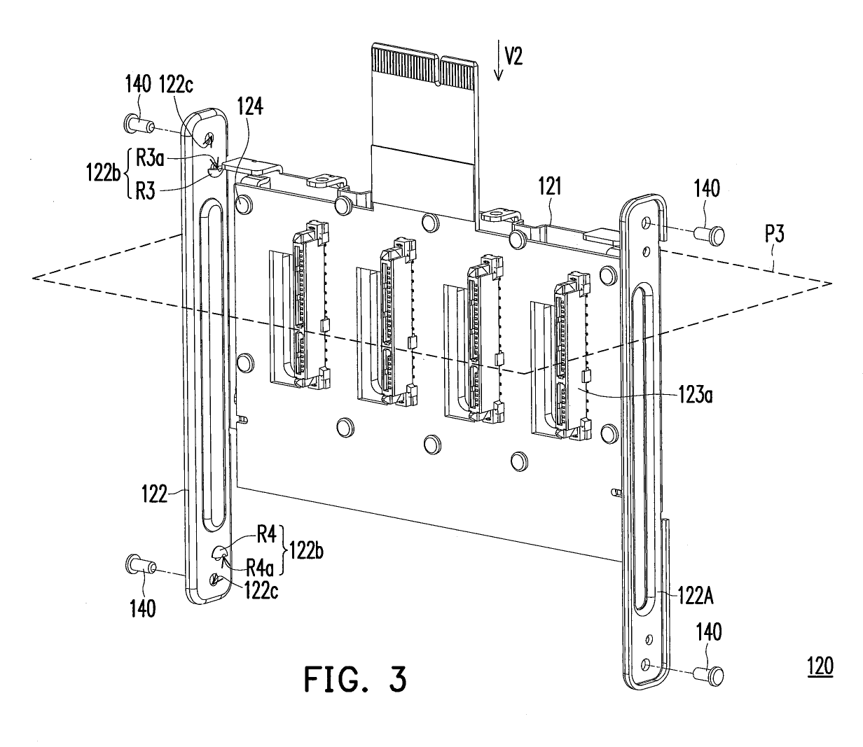

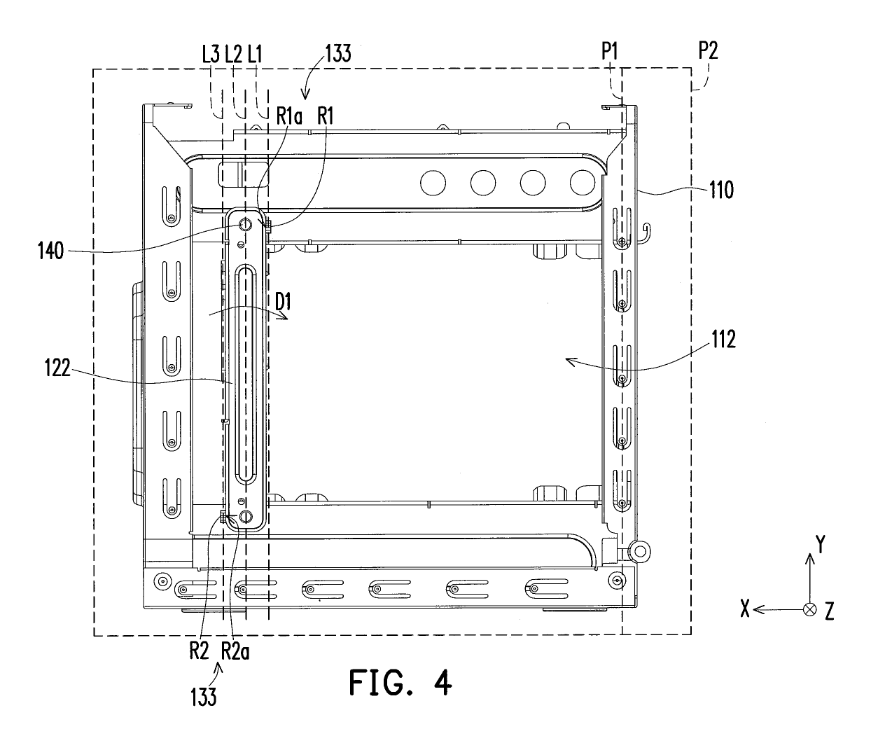

FIG. 3 is a schematic diagram of the circuit board module in the NAS of FIG. 1 and FIG. 4 is a side-view of the NAS of FIG. 1. Referring to FIGS. 1, 3 and 4, in the embodiment, the second plane P2 is formed by X-axis and Y-axis orthogonal to each other, and the X-axis is perpendicular to the first plane P1, i.e., the first plane P1 is formed by the Y-axis and Z-axis orthogonal to each other. The circuit board module 120 further includes a carry frame 121, a circuit board 123 and a plurality of screws 124 (only one is labelled), in which the brackets 122 and 122A extend respectively towards the second openings 112 and 112A from the carry frame 121 to become a plate parallel to the second plane P2 or P2A. In this way, in the angle-of-view V2 (i.e., in a viewing direction perpendicular to a third plane P3 formed by X-axis and Z-axis orthogonal to each other), the carry frame 121 and the brackets 122 and 122A are in a U-shape of structure. The circuit board 123 is fastened on the carry frame 121 by the screws 124, the brackets 122 and 122A are located at the two opposite sides of the circuit board 123 nearby the second openings 112 and 112A, so that the orthogonal projections of the circuit board 123 and the brackets 122 and 122A on the third plane P3 are in a H-shape profile.

After the circuit board module 120 is assembled, since the lengths of the first opening 111 along the Y-axis and the Z-axis are respectively less than the lengths of the brackets 122 and 122A, the user places the circuit board module 120 into the chassis 110 through the second opening 112 or 112A only. It should be noted that, referring to FIG. 4 again, since the length of the second opening 112 along the X-axis is greater than the length of the bracket 122 along the X-axis, and the length of the second opening 112 along the Y-axis is less than the length of the bracket 122 along the Y-axis, the user places the circuit board module 120 into the chassis 110 only in an orientation not parallel to the first plane P1. After that, the bracket 122 of the circuit board module 120 is rotated along a locking direction D1 so that the bracket 122 interferes with the first positioning assembly 113 on the chassis 110, which will be explained in following.

In the embodiment, the first positioning assembly 113 includes a first element R1 and a second element R2, and the first element R1 and the second element R2 are disposed on the second plane P2 respectively at an upper-right position and a lower-left position. Thereby, the locking direction D1 of the embodiment is a clockwise direction on the second plane P2 (if the circuit board module 120 is rotated in a counter-clockwise direction, the interferences between the circuit board module 120 and the first element R1 and the second element R2 are released). On the contrary, the bracket 122A of the circuit board module 120 at the other side is located at the second opening 112A at the other side of the chassis 110, and the first element R1 and the second element R2 of the first positioning assembly 113A herein is in an upper-left position and a lower-right position in angle-of-view V3 (shown in FIG. 1). Thereby, the circuit board module 120 should be rotated in the counter-clockwise direction to interfere with the first positioning assembly 113A in the angle-of-view V3. In other words, the first element R1 and the second element R2 on the second plane P2 are located at the two opposite sides of the bracket 122, and the centre lines of the first element R1, the second element R2 and the bracket 122 are respectively located on different lines L1, L2 and L3 all parallel to the Y-axis so that an effect of mutual dislocation is produced, such that the bracket 122 interfered with the first element R1 and the second element R2 in the clockwise direction (i.e., the locking direction D1 of the embodiment) or in the counter-clockwise direction (for the second opening 112A at the other side) only because of the positions of the first and the second elements R1 and R2 relative to the bracket.

The first element R1 and the second element R2 in the embodiment respectively have a first retaining portion R1a and a first retaining portion R2a. On the second plane P2 formed by the X-axis and the Y-axis, the first retaining portions R1a and R2a are respectively a line segment parallel to the Y-axis, which allows the side-edges of the bracket 122 respectively leaning against the first retaining portions R1a and R2a to produce a position-limiting effect on the bracket 122 along the X-axis.

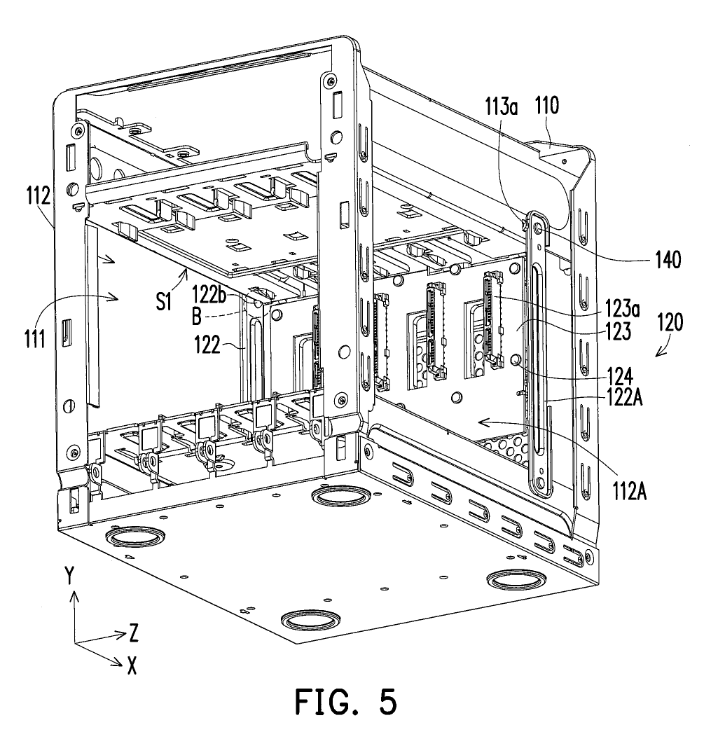

FIG. 5 is a diagram of the NAS of FIG. 1 in another angles-of-view. Referring to A portion of FIG. 1 and B portion of FIG. 5 and FIG. 3, the bracket 122 is described as an example. In the embodiment, the bracket 122 further has a second positioning assembly 122b, which is divided into a third element R3 and a fourth element R4 arranged along the Y-axis. The third element R3 and the fourth element R4 respectively have a second retaining portion R3a and a second retaining portion R4a. The second retaining portion R3a and the second retaining portion R4a are respectively a line segment parallel to the X-axis on the second plane P2. When the bracket 122 gets interferences with the first element R1 and the second element R2 of the first positioning assembly 113 as described above, the third element R3 and the fourth element R4 of the bracket 122 would interfere with the two side-edges S1 and S2 of the chassis 110 at the second opening 112 simultaneously to further produce a position-limiting effect on the bracket 122 along the Y-axis. That is to say, the bracket 122 is position-limited on the second plane P2 through the above-mentioned interference. In the same way, the second opening 112A of the chassis 110 at the other side and the bracket 122A of the circuit board module 120 have the same structures and interference effect, which is omitted to describe.

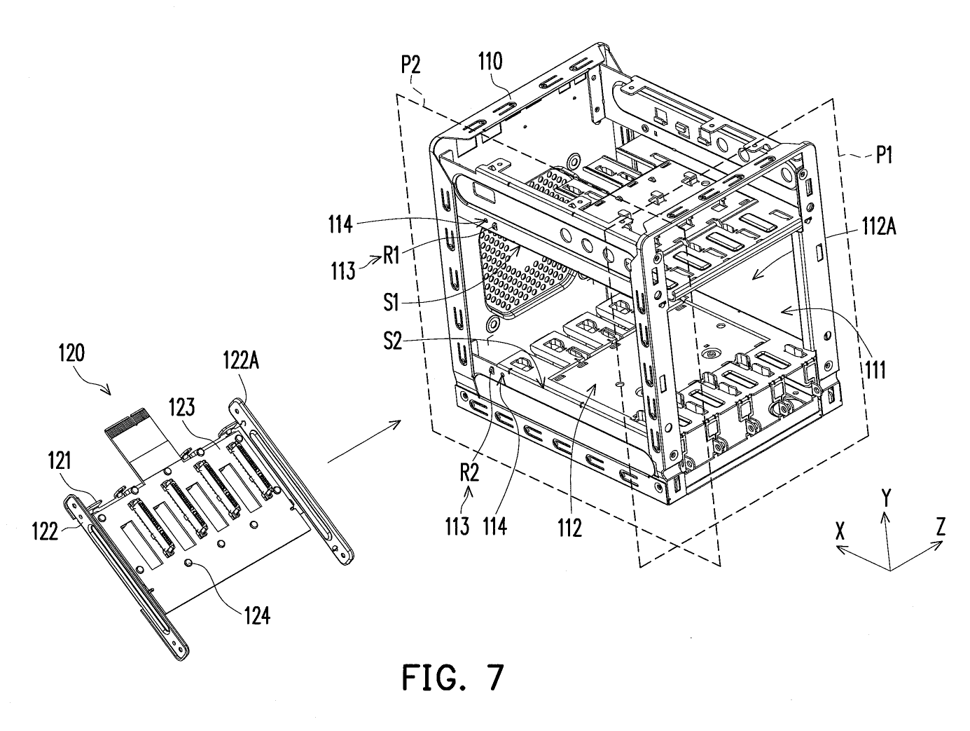

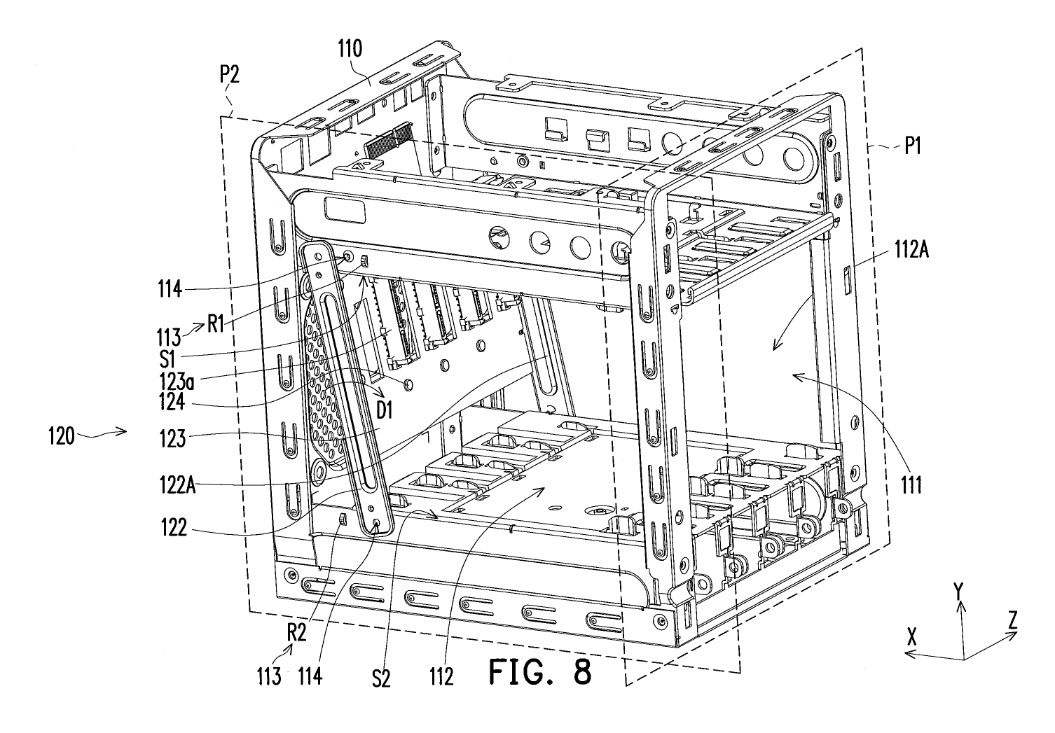

Referring to FIGS. 1-3, in the embodiment, the NAS 100 further includes a plurality of screws 140, the bracket 122 further has a plurality of first fastening holes 122c and the chassis 110 further has a plurality of second fastening holes 114 (shown in FIGS. 7 and 8). When the bracket 122 rotates along the locking direction D1 and interferes with the first positioning assembly 113, the first fastening holes 122c are aligned with the second fastening holes 114. At the time, the screws 140 are fastened at the first fastening holes 122c and the second fastening holes 114 so as to fix the bracket 122 on the chassis 110.

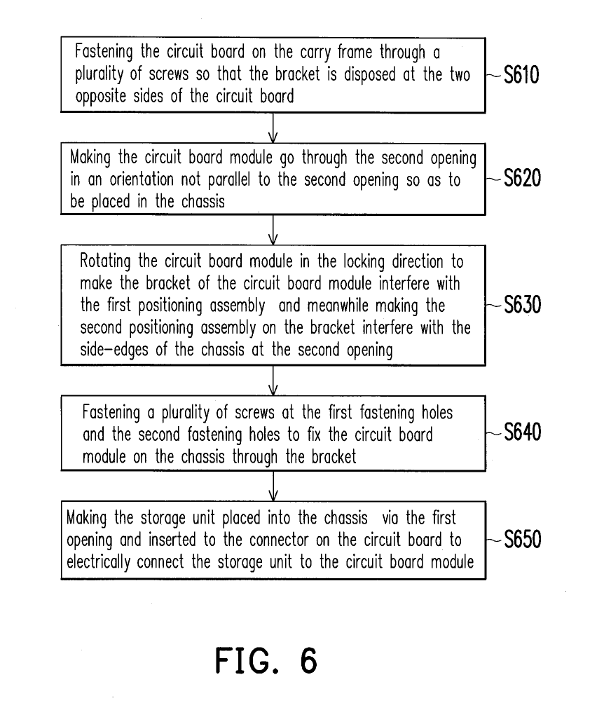

FIG. 6 is a flowchart of assembling an NAS according to an embodiment of the invention, FIGS. 7 and 8 are schematic diagrams corresponding to partial flowcharts of FIG. 6. Referring to FIGS. 6-8, in the embodiment, first in step S610, the circuit board 123 is fastened on the carry frame 121 through a plurality of screws 124 so that the bracket 122 is disposed at the two opposite sides of the circuit board 123 to finish the circuit board module 120 (as shown by FIG. 3).

Referring to FIG. 7, in step S620, the circuit board module 120 goes through the second opening 112 or 112A to be placed in the chassis 110 (in the embodiment, the second opening 112 is explained and the second opening 112A can refer to the second opening 112 for understanding), in which the circuit board module 120 passes through the second opening 112 in an orientation not parallel to the first plane P1, and the included angle between the circuit board module 120 and the first plane P1 is not limited. Since the length of the second opening 112 in the Y-axis is less than the length of the bracket 122, the user can move the circuit board module 120 into the chassis 110 in any orientation angle inclined to the first plane P1 and any appropriate inclined angles are suitable to the embodiment. Further in step S630, the circuit board module 120 is rotated in the locking direction D1 (the clockwise direction on the second plane P2) to make the bracket 122 of the circuit board module 120 interfere with the first positioning assembly 113 (i.e., the state of FIG. 9 is changed to the state of FIG. 3 by rotation). Meanwhile, the second positioning assembly 122b on the bracket 122 interferes with the side-edges S1 and S2 of the chassis 110 at the second opening 112 so as to limit the position of the bracket 122 on the second plane P2.

Since during the interfering between the bracket 122 and the chassis 110, the first fastening holes 122c of the bracket 122 are aligned with the second fastening holes 114 of the chassis 110, in step S640, the user can use a plurality of screws 140 to be fastened at the first fastening holes 122c and the second fastening holes 114 to fix the circuit board module 120 on the chassis 110 through the bracket 122. At the time, the circuit board module 120 is disposed in the chassis 110 in an orientation parallel to the first plane P1, and a connector 123a on the circuit board 123 at the time is right aligned with the first opening 111. Finally in step S650, the storage unit 130 is placed into the chassis 110 via the first opening 111 and inserted to the connector 123a on the circuit board 123 to make the storage unit 130 and the circuit board module 120 electrically connected to each other. At the time, the storage unit 130 takes an orientation parallel to the second plane P2 or P2A. The flowchart of assembling the NAS 100 of the embodiment is finished.

In summary, in the above-mentioned embodiments of the invention, the circuit board module of the NAS can be assembled to the chassis in this way through the structure designs of the brackets and carry frame thereof: assembling the circuit board to the carry frame first; after the brackets are located at the two opposite sides of the circuit board, rotating the circuit board module in a specific direction to make the brackets and the chassis interfere with each other so as to achieve the effect of assembling the circuit board module to the chassis. In this way, the NAS of the invention is able for the user to conveniently assemble the circuit board module in the chassis through the above-mentioned simple structure designs, which is advantageous in strengthening the structure of the chassis and advancing the assembling efficiency of the NAS.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. A network attached storage device, comprising:
a chassis, having a first opening, at least one second opening and at least one first positioning assembly, wherein the first positioning assembly is located beside the second opening;
a circuit board module, placed into the chassis via the second opening, wherein the circuit board module has at least one bracket and the bracket is located at the second opening and interferes with the first positioning assembly along a locking direction; and
at least one storage unit, placed into the chassis via the first opening so as to be assembled and electrically connected to the circuit board module.

2. The network attached storage device as claimed in claim 1, wherein the first opening is located on a first plane, both the second opening and the first positioning assembly are located on a second plane, and the first plane is perpendicular to the second plane.

3. The network attached storage device as claimed in claim 2, wherein the second plane is formed by a first axis and a second axis orthogonal to each other and the first axis is perpendicular to the first plane.

4. The network attached storage device as claimed in claim 3, wherein the circuit board module comprises:
a carry frame, wherein the bracket extends towards the second opening from the carry frame to be assembled to the chassis; and
a circuit board, assembled on the carry frame and together with the carry frame parallel to the second axis, wherein the storage unit is inserted to the circuit board along the first axis.

5. The network attached storage device as claimed in claim 4, wherein the chassis has two second openings respectively located on two second planes parallel to each other, the first plane is perpendicular to the two second planes and orthogonal projections of the two second openings on the first plane are respectively located at both opposite sides of the first opening.

6. The network attached storage device as claimed in claim 5, wherein the circuit board module comprises two brackets respectively extending to the two second openings from the carry frame, wherein orthogonal projections of the two brackets and the circuit board on a third plane taking the second axis as the normal thereof are in a H-shape.

7. The network attached storage device as claimed in claim 3, wherein the first positioning assembly comprises a first element and a second element respectively leaning against both opposite sides of the bracket, and the first element and the second element on the second plane are located on different lines parallel to the second axis.

8. The network attached storage device as claimed in claim 7, wherein the first element and the second element on the second plane are disposed at upper-left and lower-right positions or lower-left and upper-right positions relatively to the bracket.

9. The network attached storage device as claimed in claim 7, wherein the first element and the second element respectively have a first retaining portion, the bracket gets interference between the two first retaining portions, and each of the first retaining portions on the second plane is a line segment parallel to the second axis.

10. The network attached storage device as claimed in claim 3, wherein the chassis has a pair of side-edges opposite to each other beside the second opening, the bracket further has a second positioning assembly, and the second positioning assembly leans against the pair of side-edges along the second axis.

11. The network attached storage device as claimed in claim 10, wherein the second positioning assembly comprises a third element and a fourth element arranged along the second axis, the third element and the fourth element respectively have a second retaining portion leaning against the pair of side-edges, and each of the second retaining portions projected on the second plane is a line segment parallel to the first axis.

12. The network attached storage device as claimed in claim 3, wherein a length of the second opening along the first axis is greater than a length of the bracket along the first axis, and a length of the second opening along the second axis is less than a length of the bracket along the second axis.

13. The network attached storage device as claimed in claim 2, wherein the first plane is formed by a third axis and a fourth axis orthogonal to each other, wherein the third axis is perpendicular to the second plane, a length of the first opening along the third axis is less than a length of the bracket along the third axis, and a length of the first opening along the fourth axis is less than a length of the bracket along the fourth axis.

14. The network attached storage device as claimed in claim 2, wherein a projection of the locking direction on the second plane is in a clockwise direction or a counter-clockwise direction.

15. The network attached storage device as claimed in claim 1, further comprising at least one screw, wherein the bracket has at least one first fastening hole, the chassis has at least one second fastening hole, when the bracket interferes with the first positioning assembly along the locking direction, the first fastening hole is aligned with the second fastening hole, and the screw is fastened at the first fastening hole and the second fastening hole to fix the bracket on the chassis.

16. A method of assembling a network attached storage device, wherein the network attached storage device comprises a chassis, a circuit board module and at least one storage unit, the chassis has a first opening, two second openings and two first positioning assemblies, wherein the two first positioning assemblies are respectively located beside the corresponding second openings; the method of assembling a network attached storage device comprising:
placing the circuit board module into the chassis along an axis via one of the second openings;
rotating the circuit board module along a locking direction to make at least one bracket of the circuit board module interfere with the first positioning assembly;
fixing the bracket to the chassis;
placing the storage unit into the chassis via the first opening; and
assembling and electrically connecting the storage unit to the circuit board module.

17. The method of assembling a network attached storage device as claimed in claim 16, wherein the first opening is located on a first plane, the two second openings are respectively located on two second planes parallel to each other, the first plane is perpendicular to the two second planes, when the circuit board module goes through the second opening to be placed in the chassis, the circuit board module is not parallel to the first plane, and when the circuit board module interferes with the first positioning assembly, the circuit board module is parallel to the first plane.

18. The method of assembling a network attached storage device as claimed in claim 17, wherein the second plane is formed by a first axis and a second axis orthogonal to each other, the first axis is perpendicular to the first plane and the bracket and the first positioning assembly are position-limited by each other along the first axis.

19. The method of assembling a network attached storage device as claimed in claim 18, wherein the bracket further has a second positioning assembly, and when the bracket interferes with the first positioning assembly, the second positioning assembly and the side-edge of the second opening are position-limited by each other along the second axis.

20. The method of assembling a network attached storage device as claimed in claim 16, wherein the locking direction projected on the second plane is in a clockwise direction or a counter-clockwise direction.

21. The method of assembling a network attached storage device as claimed in claim 20, wherein each of the first positioning assemblies is located on a rotation path of the circuit board module along the clockwise direction or on a rotation path of the circuit board module along the counter-clockwise direction.

22. The method of assembling a network attached storage device as claimed in claim 16, wherein the bracket has at least one first fastening hole, the chassis has at least one second fastening hole, the network attached storage device further comprises a plurality of screws and the method of assembling a network attached storage device further comprises:
when the bracket of the circuit board module is locked at the first positioning assembly, the first fastening hole is aligned with the second fastening hole; and
fastening the screws at the first fastening hole and the second fastening hole so as to fix the bracket on the chassis.

23. The method of assembling a network attached storage device as claimed in claim 16, wherein the circuit board module comprises a carry frame, two brackets, a circuit board and a plurality of screws, the two brackets extend respectively from both sides of the carry frame so that the carry frame and the two brackets form a U-shape structure, and the method of assembling a network attached storage device further comprises:
fastening the circuit board on the carry frame through the screws to make the two brackets located at both opposite sides of the circuit board.
